(19) United States
(12) Patent Application Publication
(10) Pub. No.: US 2011/0084248 A1
(43) Pub. Date: Apr. 14, 2011

(54) CROSS POINT MEMORY ARRAY DEVICES

(75) Inventors: Chun-I Hsieh, Taoyuan County (TW); Chang-Rong Wu, Taoyuan County (TW)

(73) Assignee: NANYA TECHNOLOGY CORPORATION, Taoyuan (TW)

(21) Appl. No.: 12/578,496

(22) Filed: Oct. 13, 2009

(51) Int. Cl. H01L 47/00; H01L 29/12

(52) U.S. Cl. 257/4; 257/E47.001; 257/43

(57) ABSTRACT

Cross point memory arrays with CBRAM and RRAM stacks are presented. A cross point memory array includes a first group of substantially parallel conductive lines and a second group of substantially parallel conductive lines, oriented substantially perpendicular to the first group of substantially parallel conductive lines. An array of memory stack is located at the intersections of the first group of substantially parallel conductive lines and the second group of substantially parallel conductive lines, wherein each memory stack comprises a conductive bridge memory element in series with a resistive-switching memory element.

### BACKGROUND OF THE INVENTION

1. Field of the Invention

The invention relates to cross point memory array devices, and in particular, to a cross point memory array with memory stack including a conductive bridge memory element in series with a resistive-switching memory element.

2. Description of the Related Art

Conventional nonvolatile memories require three terminal MOSFET-based devices. The layout of such devices is not ideal, usually requiring feature sizes of 8f² for each memory cell, where f is the minimum feature size. A cross point memory array such as a programmable metallization cell random access memory (PMCRAM) also known as a conductive bridge random access memory (CBRAM), a phase change memory (PCM), and a resistive random access memory (RRAM) are promising alternatives to conventional three terminal MOSFET-based devices, due to their smaller required feature sizes of 4f² per cross points.

U.S. Pat. No. 6,753,561, the entirety of which is hereby incorporated by reference, discloses a cross point memory array using conductive array lines and multiple thin films as a memory plug. The thin films of the memory plug include a memory element and a non-ohmic device. The thin film layer switches from a first resistance state to a second resistance state upon application of a first write voltage pulse to the memory element and reversibly switches from the second resistance state back to the first resistance state upon application of a second write voltage pulse to the memory element having opposite polarity of the first write voltage pulse.

FIG. 1 is a cross section schematically illustrating a conventional cross point memory array using multiple thin films. Referring to FIG. 1, a memory plug 5 with seven separate thin-film layers is sandwiched between two conductive array lines 10 and 15. The seven layers comprise: an electrode layer 20, a layer of metal oxide material 25 (providing the memory element), another optional electrode layer 30, three layers that make up a metal-insulator-metal (MIM) structure 35, 40 and 45 (providing the non-ohmic device), and an optional final electrode 50. The metal-insulator-metal (MIM) structure is used to drive the memory element. However, the MIM tunneling junction is slow, unreliable, and lacks unidirectional switching functions. In some related prior art, a semiconductor diode is used as a current-driven device, for example, a p-n junction diode. However, incorporating the p-n junction diode in a cross point memory is complex and it is difficult to scale down the p-n junction diode due to current supply limitations.

Crosstalk between adjacent memory cells, however, is the most critical issue for conventional cross point memory arrays, because the threshold voltage thereof is too small to resist noise.

U.S. Pat. No. 7,236,389, the entirety of which is hereby incorporated by reference, discloses a circuit for eliminating cross talk between bit lines in a cross-point RRAM memory array. A high-open-circuit voltage gain amplifier is used as a bit line sensing differential amplifier to minimize the cross talk among bit lines. The additional circuit and high-open-circuit voltage gain amplifier, however, occupies additional device space and increases fabrication complexity.

### BRIEF SUMMARY OF THE INVENTION

An embodiment of the invention provides a cross point memory array, comprising: a first group of substantially parallel conductive lines; a second group of substantially parallel conductive lines, oriented substantially perpendicular to the first group of substantially parallel conductive lines; and an array of memory stack located at the intersections of the first group of substantially parallel conductive lines and the second group of substantially parallel conductive lines, wherein each memory stack comprises a conductive bridge memory element in series with a resistive-switching memory element.

Another embodiment of the invention provides a cross point memory array, comprising: a first group of substantially parallel conductive lines; a second group of substantially parallel conductive lines, oriented substantially perpendicular to the first group of substantially parallel conductive lines; and an array of memory stack located at the intersections of the first group of substantially parallel conductive lines and the second group of substantially parallel conductive lines, wherein each memory stack comprises a resistive-switching memory element that is switched by a unidirectional selective device.

### BRIEF DESCRIPTION OF THE DRAWINGS

The invention can be more fully understood by reading the subsequent detailed description and examples with references made to the accompanying drawings, wherein:

FIG. 1 is a cross section schematically illustrating a conventional cross point memory array using multiple thin films;

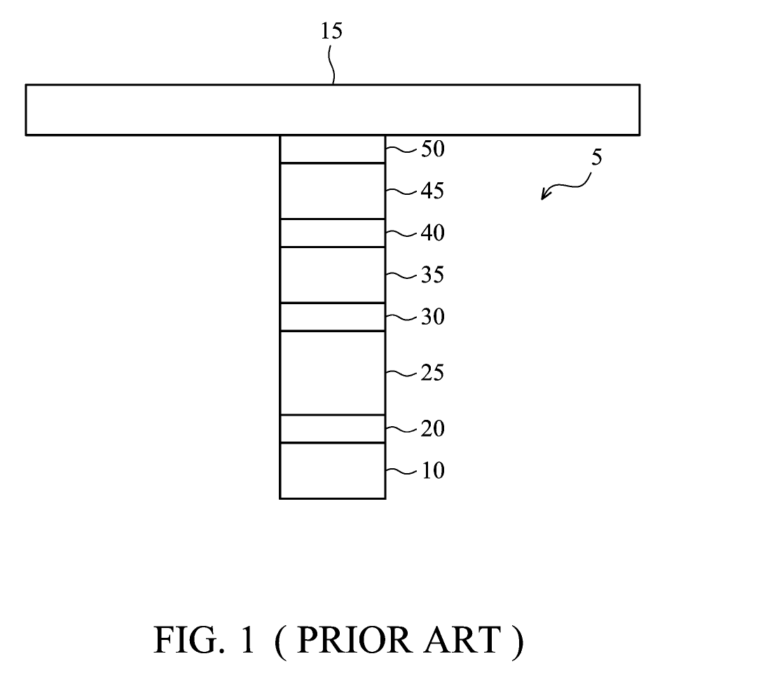

FIG. 2 is a schematic view illustrating an embodiment of the cross point memory array of the invention;

FIG. 3 is a cross section of an exemplary embodiment of the cross point memory device of the invention;

FIG. 4 is a schematic diagram depicting an equivalent circuit of an embodiment of the cross point memory array; and

FIG. 5 is a schematic view illustrating an embodiment of the three dimensional cross point memory array of the invention.

### DETAILED DESCRIPTION OF THE INVENTION

It is to be understood that the following disclosure provides many different embodiments, or examples, for implementing different features of various embodiments. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed in direct contact or not in direct contact.

As key aspects and main features, embodiments of the invention provide a cross point memory array device. The cross point memory array with dual RRAM devices comprises a first group of substantially parallel conductive lines and a second group of substantially parallel conductive lines, oriented substantially perpendicular to the first group of substantially parallel conductive lines. An array of memory stack are located at the intersections of the first group of substantially parallel conductive lines and the second group of substantially parallel conductive lines, wherein each memory stack comprises a conductive bridge memory element in series with a resistive-switching memory element.

Among emerging resistive-driven memory technologies, the conductive bridging random access memory (CBRAM) is of particular interest due to its excellent scaling potential in the sub-20 nm range and low power consumption. This technology utilizes electrochemical redox reactions to form nanoscale metallic filaments in an isolating amorphous solid electrolyte. A conductive bridge RAM (CBRAM) comprises memory cells on a base of an alterable resistance active solid electrolyte embedded between two electrodes applying given electric fields to switch between a high resistance OFF and a low resistance ON states.

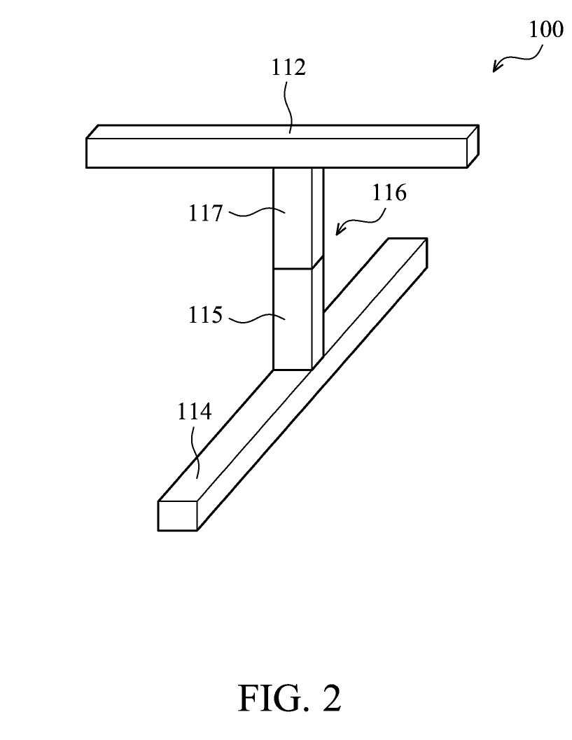

FIG. 2 is a schematic view illustrating an embodiment of the cross point memory array of the invention. In FIG. 2, an exemplary cross point memory device 100 includes a cross point memory stack 116 sandwiched between two conductive array lines 112 and 114. The cross point memory stack 116 includes a conductive bridge memory element 117 in series with a resistive-switching memory element 115.

The conductive bridge memory element 117, serving as a selective device, operates quickly when driven by low current and the resistive-switching memory element 115, operate slower when driven by high current.

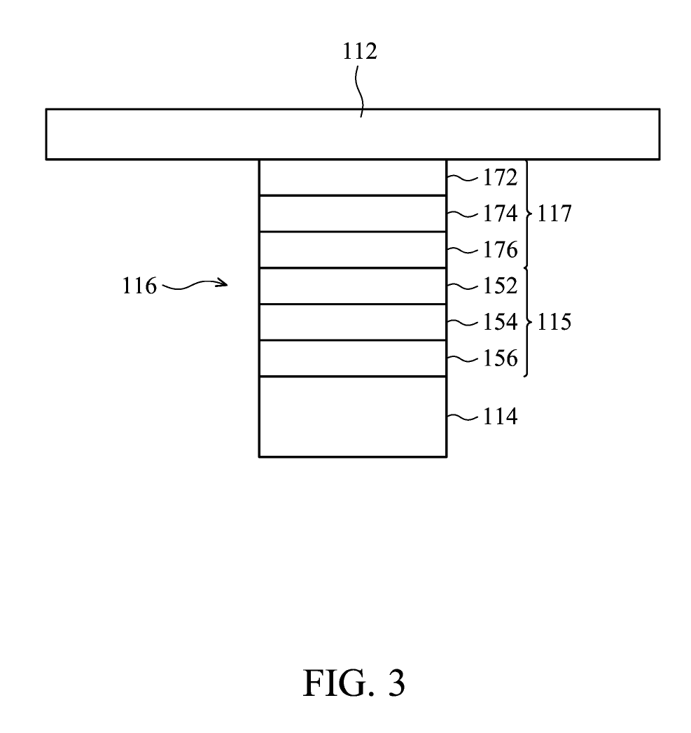

FIG. 3 is a cross section of an exemplary embodiment of the cross point memory device of the invention. Referring to FIG. 3, an exemplary memory stack 116 with at least six separate thin-film layers are provided, sandwiched between two conductive array lines 112 and 114. The six layers are, in sequence: an electrode layer 156, a layer of metal oxide material 154, another electrode layer 152, a cathode layer 176, a solid electrolyte layer 174 and an anode 172. The electrode layer 156, the layer of metal oxide material 154, and the electrode layer 152 make up a resistive-driven memory structure 115. The metal oxide materials can be PCMO, TiOₓ, AlOₓ, TaOₓ, HfOₓ, WOₓ, NiOₓ and the likes. The cathode layer 176, the solid electrolyte layer 174, and the anode 172 make up a conductive bridging RAM (CBRAM) element 117. The CBRAM element 117 is a unidirectional current driven device which can serve as a selective driver for the resistive-driven memory structure 115.

In one embodiment, the resistive-switching memory element 115 comprises a memory element 154 interposed between two electrodes 152 and 156. The memory element 154 can be a metal oxide material with a perovskite structure. The metal oxide material comprises two or more metals, and the metals are selected from the group consisting of transition metals, alkaline earth metals and rare earth metals. The metal oxide material includes Pr_{0.7}Ca_{0.3}MnO₃ or Pr_{0.7}Ca_{0.3}MnO₃.

In another embodiment, the conductive bridge memory element 117 comprises a base of alterable resistance active solid electrolyte 174 embedded between a top electrode 172 and a bottom electrode 176. Typical electrodes 172 and 176 commonly used for fabrication include Pt, Au, Ag and Al. The active solid electrolyte 174 can be a compound electrolyte containing GeSe. The top electrode 172 can be an anode comprising Ag or Cu. The bottom electrode 176 can be a cathode comprising noble metals such as Pt on TiN.

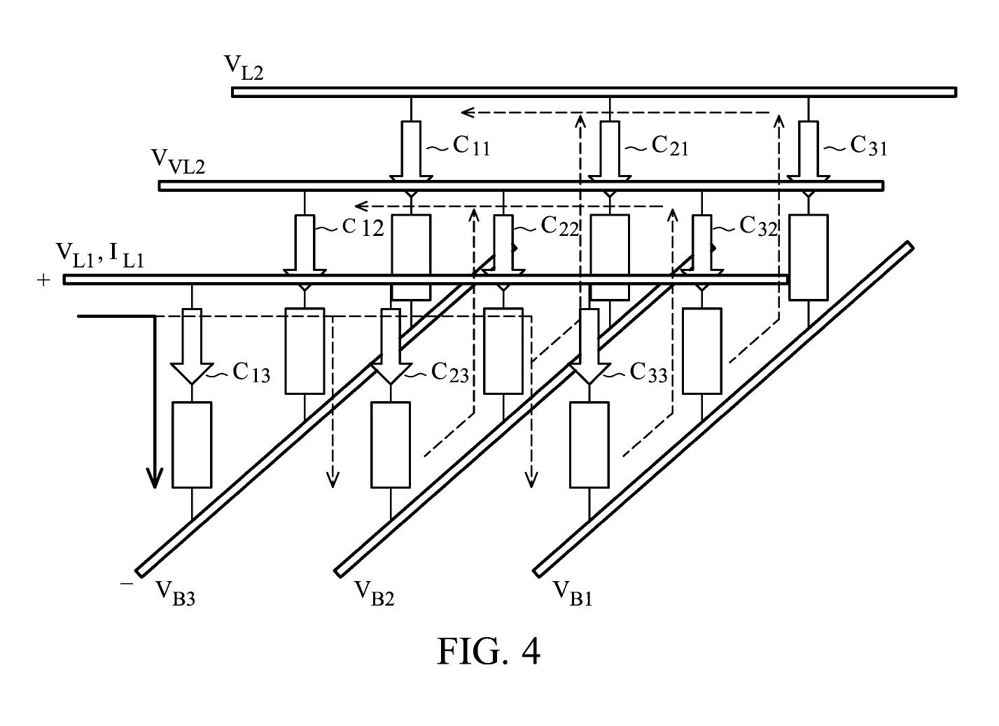

FIG. 4 is a schematic diagram depicting an equivalent circuit of an embodiment of the cross point memory array. In FIG. 4, since the CBRAM element of each memory stack Cᵢⱼ can be switched faster than the RRAM element, the unidirectional current driven CBRAM can effectively suppress reverse leakage current and crosstalk between adjacent memory stacks. When a voltage V_{LI} is applied to a word line and a bit line V_{B3}, the memory stack C₁₃ is programmed (solid line). Without the CBRAM device, however, the cross point array may have multi leakage paths (dotted lines) over each cross point and serious crosstalk between bit lines may completely distort memory signal output. Since the CBRAM device is a unidirectional current driven device, reverse leakage current is suppressed, thus eliminating cross talk between bit lines.

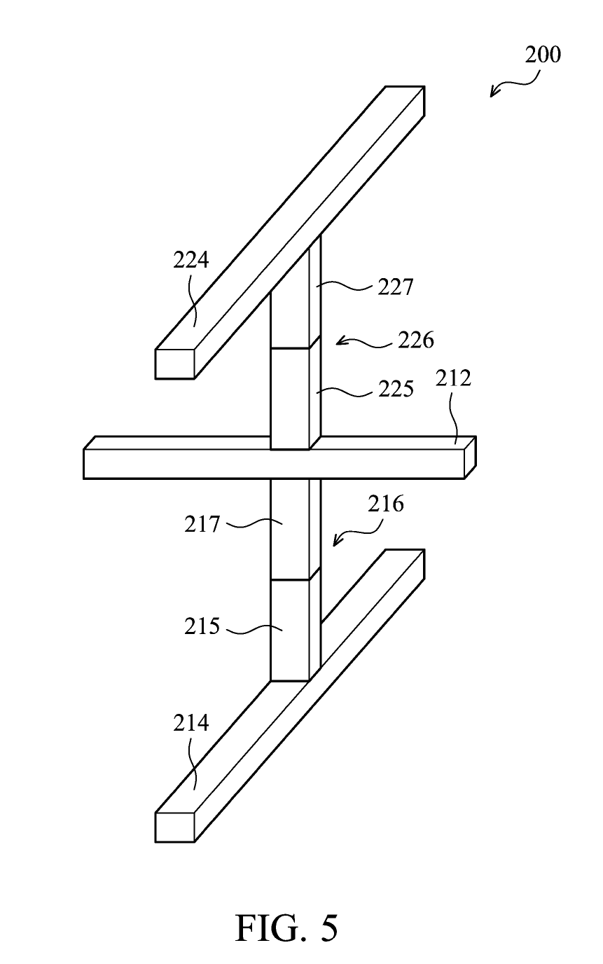

FIG. 5 is a schematic view illustrating an embodiment of the three dimensional cross point memory array of the invention. In FIG. 5, an exemplary three dimensional cross point memory device 200 includes a first cross point memory stack 216 sandwiched between a first pair of conductive array lines 212 and 214. The cross point memory stack 216 includes a first conductive bridge memory element 217 in series with a first resistive-switching memory element 215. A second cross point memory stack 226 is sandwiched between a second pair of conductive array lines 212 and 224. The cross point memory stack 226 includes a first conductive bridge memory element 227 in series with a first resistive-switching memory element 225. Therefore, the cross point memory stack can be vertically replicated to implement multi-bits in a single cross point.

Some embodiments of the cross point memory array devices are advantageous in that each memory stack comprises a resistive-switching memory element switched by a unidirectional selective device. By comparison with the conventional MIM junction device, the CBRAM device operates faster and more reliable than the MIM junction device. By comparison with the convention p-n junction diode, the CBRAM device can be operated at lower voltage and output with higher current.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A cross point memory array, comprising:
a first group of substantially parallel conductive lines;
a second group of substantially parallel conductive lines, oriented substantially perpendicular to the first group of substantially parallel conductive lines; and
an array of memory stack located at the intersections of the first group of substantially parallel conductive lines and the second group of substantially parallel conductive lines,
wherein each memory stack comprises a conductive bridge memory element in series with a resistive-switching memory element.

2. The cross point memory array as claimed in claim 1, wherein the conductive bridge memory element comprises a base of an alterable resistance active solid electrolyte embedded between a top electrode and a bottom electrode.

3. The cross point memory array as claimed in claim 2, wherein the active solid electrolyte comprises a compound electrolyte containing GeSe.

4. The cross point memory array as claimed in claim 2, wherein the top electrode is an anode comprising Ag or Cu.

5. The cross point memory array as claimed in claim 2, wherein the bottom electrode is a cathode comprising noble metals.

6. The cross point memory array as claimed in claim 1, wherein the resistive-switching memory element comprises a memory element interposed between two electrodes.

7. The cross point memory array as claimed in claim 6, wherein the memory element comprises metal oxide materials.

8. The cross point memory array as claimed in claim 7, wherein the metal oxide materials include a perovskite structure.

9. The cross point memory array as claimed in claim 7, wherein the metal oxide materials comprise two or more metals, and the metals are selected from the group consisting of transition metals, alkaline earth metals and rare earth metals.

10. The cross point memory array as claimed in claim 7, wherein the metal oxide materials include Pr_{0.7}Ca_{0.3}MnO₃ or Pr_{0.7}Ca_{0.3}MnO₃.

11. A cross point memory array, comprising:
a first group of substantially parallel conductive lines;
a second group of substantially parallel conductive lines, oriented substantially perpendicular to the first group of substantially parallel conductive lines; and
an array of memory stack located at the intersections of the first group of substantially parallel conductive lines and the second group of substantially parallel conductive lines,
wherein each memory stack comprises a resistive-switching memory element that is switched by a unidirectional selective device.

12. The cross point memory array as claimed in claim 11, wherein the resistive-switching memory element comprises a memory element interposed between two electrodes.

13. The cross point memory array as claimed in claim 12, wherein the memory element includes metal oxide materials.

14. The cross point memory array as claimed in claim 13, wherein the metal oxide materials include a perovskite structure.

15. The cross point memory array as claimed in claim 13, wherein the metal oxide materials comprise two or more metals, and the metals are selected from the group consisting of transition metals, alkaline earth metals and rare earth metals.

16. The cross point memory array as claimed in claim 13, wherein the metal oxide materials include Pr_{0.7}Ca_{0.3}MnO₃ or Pr_{0.7}Ca_{0.3}MnO₃.

17. The cross point memory array as claimed in claim 11, wherein the unidirectional selective device comprises a programmable metallization cell random access memory (PMCRAM) or a conductive bridge random access memory (CBRAM).

18. The cross point memory array as claimed in claim 17, wherein the CBRAM comprises a base of an alterable resistance active solid electrolyte embedded between a top electrode and a bottom electrode.

19. The cross point memory array as claimed in claim 18, wherein the active solid electrolyte comprises a compound electrolyte containing GeSe.

20. The cross point memory array as claimed in claim 18, wherein the top electrode is an anode comprising Ag or Cu.

21. The cross point memory array as claimed in claim 18, wherein the bottom electrode is a cathode comprising noble metals.
